(19) United States
(12) Patent Application Publication
(10) Pub. No.: US 2026/0229866 A1
(43) Pub. Date: Aug. 6, 2026

(54) RACK BUSBAR ASSEMBLY

(71) Applicant: BIZLINK INTERNATIONAL CORP., New Taipei City (TW)

(72) Inventors: Zengshi LAO, New Taipei City (TW); Haoran ZOU, New Taipei City (TW)

(21) Appl. No.: 19/564,207

(22) Filed: Mar. 12, 2026

Related U.S. Application Data
(63) Continuation-in-part of application No. 19/457,169, filed on Jan. 23, 2026.

(30) Foreign Application Priority Data
Jan. 24, 2025 (CN) 202510120742.6
Mar. 12, 2025 (CN) 202510294150.6

(51) Int. Cl. H02G 5/10; H01B 17/18; H02G 5/02; H02G 5/04; H05K 7/20

(52) U.S. Cl. CPC H02G 5/10; H01B 17/18; H02G 5/025; H02G 5/04; H05K 7/20254; H05K 7/20263; H05K 7/20272

(57) ABSTRACT

A rack busbar assembly includes a housing, two busbars, an insulating member, a thermal conductive element, a fastening member, and a fastener. The two busbars extend along a longitudinal direction, each comprising an upper portion and a lower portion. The insulating member is disposed between the upper portions to electrically isolate the two busbars. The thermal conductive element defines a liquid flow channel therein and is disposed adjacent to the lower portions. The fastening member is disposed at the lower portions. The fastener passes through the lower portions and the fastening member to secure the thermal conductive element relative to the two busbars. The assembly effectively integrates liquid cooling for improved heat dissipation while maintaining strict electrical isolation, structural stability, and a compact design.

### CROSS - REFERENCE TO RELATED APPLICATION

This application is a continuation-in-part of U.S. Application Serial Number 19/457,169, filed January 23, 2026, which claims priority to China Application Serial Number 202510120742.6, filed January 24, 2025.

This application also claims priority to China Application Serial Number 202510294150.6, filed March 12, 2025, which is herein incorporated by reference in its entirety.

### BACKGROUND

### FIELD OF INVENTION

The present invention relates to the field of connector technology, and more particularly to a rack busbar assembly.

### DESCRIPTION OF RELATED ART

U.S. Patent Application Publication No. 2024/0212887A1 discloses a busbar assembly for powering a server, including a housing, two busbars, and an intermediate insulating member. The busbars and the intermediate insulating member are fixed within the housing via a fastener passing through the housing, the busbars, and the intermediate insulating member.

However, similar busbars generate a significant amount of heat due to high current levels. If the heat cannot be dissipated rapidly, it may lead to busbar failure and an increased risk of malfunction. Conventional methods for heat dissipation involve using external fans on a rack or utilizing natural convection. Such designs exhibit low heat dissipation efficiency and struggle to satisfy cooling requirements as the current increases.

### SUMMARY

The main objective of the present invention is to propose a rack busbar assembly with improved heat dissipation performance and an improved design for fixing busbars.

According to one aspect of the present invention, a rack busbar assembly comprises a housing, two busbars, an insulating member, a thermal conductive element, a fastening member, and a fastener. The two busbars are disposed within the housing and extend along a longitudinal direction. Each of the two busbars comprises an upper portion and a lower portion connected to the upper portion along a height direction. The insulating member is disposed between the upper portions of the two busbars to electrically isolate the two busbars. The thermal conductive element defines a liquid flow channel therein, wherein the thermal conductive element is disposed adjacent to the lower portions of the two busbars. The fastening member is disposed at the lower portions of the two busbars. The at least one fastener passes through the lower portions of the two busbars and the fastening member to secure the thermal conductive element relative to the two busbars.

By adopting the aforementioned configuration, the rack busbar assembly of the present disclosure provides several significant advantages. The structural integration of the thermal conductive element adjacent to the lower portions of the busbars effectively utilizes the liquid cooling mechanism to significantly improve heat dissipation efficiency, which is highly beneficial for high-current and high-power applications. Furthermore, the strategic arrangement of the insulating member between the upper portions and the fastening member at the lower portions ensures strict electrical isolation between the two busbars, as well as between the busbars and the thermal conductive element. This structural design not only optimizes space utilization for a highly compact form factor but also reliably prevents electrical short circuits, thereby ensuring the overall electrical safety and structural stability of the system.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a schematic view showing an overall structure of a rack busbar assembly according to the first embodiment of the present invention;

FIG. 2 is a schematic view showing a relative relationship between a housing and a cover plate in FIG. 1;

FIG. 3 is a schematic view of FIG. 1 with the housing omitted;

FIG. 4 is an enlarged schematic view of a head portion in FIG. 3;

FIG. 5 is a partial cross-sectional view taken along line A-A in FIG. 4;

FIG. 6 is a partial cross-sectional view taken along line B-B in FIG. 4;

FIG. 7 is a schematic view showing an appearance of a thermal conductive element in a thermal conductive element group in FIG. 1;

FIG. 8 is a schematic view of the thermal conductive element in the thermal conductive element group in FIG. 1 with a portion of an outer surface removed;

FIG. 9 is a partial cross-sectional view showing a rack busbar assembly according to the second embodiment of the present invention;

FIG. 9A is a partial cross-sectional view showing a rack busbar assembly according to a variation from the second embodiment of the present invention;

FIG. 10 is a partial cross-sectional view showing a rack busbar assembly according to the third embodiment of the present invention; and

FIG. 11 is a partial cross-sectional view showing a rack busbar assembly according to the fourth embodiment of the present invention;

FIG. 12 is a perspective view illustrating the lower fastening member of the rack busbar assembly according to the fourth embodiment of the present invention; and

FIG. 13 is a schematic view of a variation of the internal design of the liquid flow channel of the thermal conductive element.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

The technical solutions in the embodiments of the present invention will be described clearly and completely below with reference to the accompanying drawings in the embodiments of the present invention. It is apparent that the described embodiments are only a portion of the embodiments of the present invention, rather than all of the embodiments. Based on the embodiments in the present invention, all other embodiments obtained by those of ordinary skill in the art without creative effort shall fall within the scope of protection of the present invention.

It should be noted that if directional indicators (such as up, down, left, right, front, back, etc.) are involved in the embodiments of the present invention, the directional indicators are only used to explain the relative positional relationship, movement, etc., between various components in a specific posture. If the specific posture changes, the directional indicators will change accordingly.

In addition, if descriptions involving "first," "second," etc., are involved in the embodiments of the present invention, the descriptions of "first," "second," etc., are for descriptive purposes only and should not be understood as indicating or implying their relative importance or implicitly indicating the number of indicated technical features. Thus, a feature defined by "first" or "second" may explicitly or implicitly include at least one such feature. Furthermore, if "and/or" appears in the text, its meaning includes three parallel solutions; taking "A and/or B" as an example, it includes solution A, solution B, or a solution where both A and B are satisfied simultaneously. In addition, the technical solutions between various embodiments can be combined with each other, provided that such combinations are based on what can be realized by those of ordinary skill in the art. When a combination of technical solutions is contradictory or impossible to achieve, such a combination should be considered non-existent and is not within the scope of protection claimed by the present invention. If the present invention mentions "A includes/comprises B," unless explicitly excluded or not allowed by the context, the inclusion or comprehension therein means that A includes one or more B.

It should be noted that the drawings of the present invention are drawn to scale, and the dimensional proportions and relative positions of various components should be considered as part of the disclosure.

The present invention provides a rack busbar assembly used for simultaneously powering a plurality of servers. By the following design, it can be ensured that the busbars are stably fixed in the housing to ensure proper operation of the device.

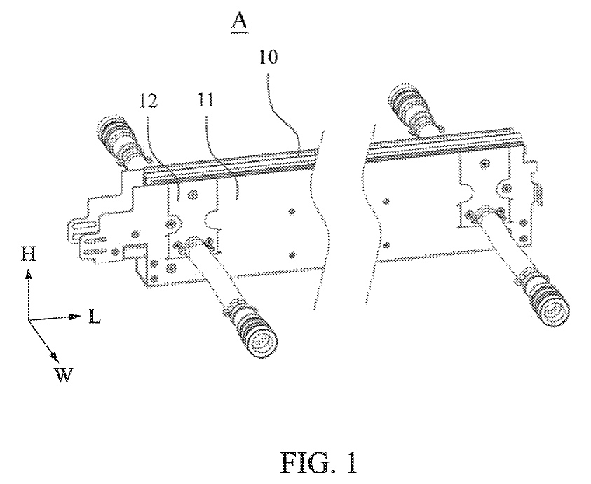

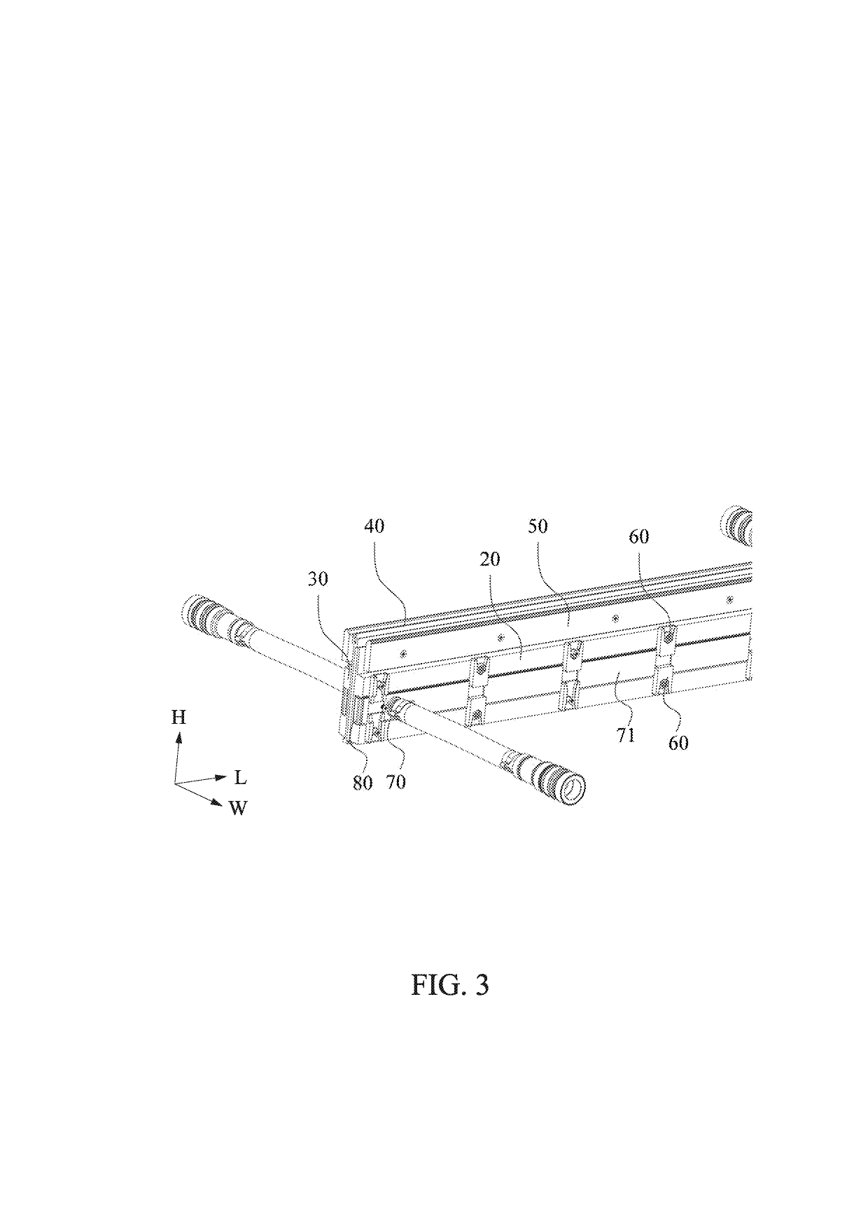

The design of the rack busbar assembly of the present invention will be explained below with a first embodiment. Referring to FIG. 1 and FIG. 3, the rack busbar assembly A includes many parts, among which the main parts are a housing 10, two busbars 20, 30, an insulating member 40, two grounding bars 50, a plurality of fastening members 60, two thermal conductive element groups 70, a thermal conductive insulating material layer 80, and a plurality of parts used for fixing, such as fasteners 90 (e.g., screws and nuts of different lengths).

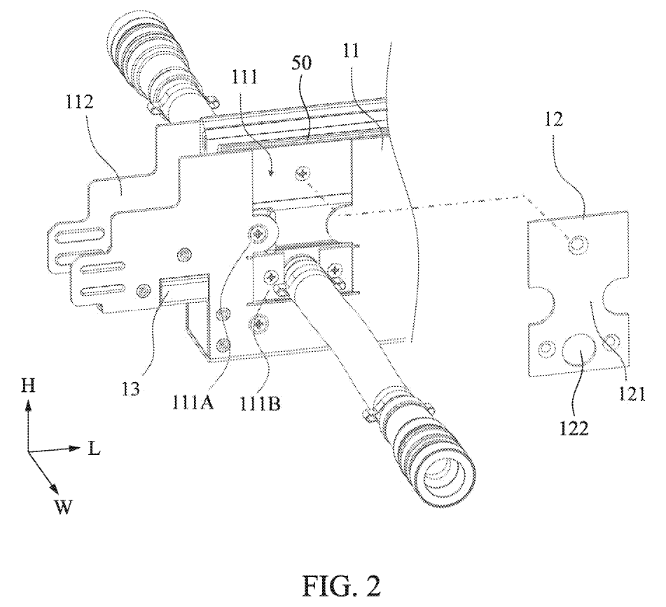

The design of the housing 10 is described below. Referring to FIG. 2, the housing 10 generally comprises a main body portion 11 and cover plates 12. The main body portion 11 of the housing 10 includes a metal frame having a substantially U-shape cross-section. The housing 10 includes two sidewalls and a bottom wall, wherein the bottom wall is perpendicularly disposed relative to the two sidewalls, and the bottom wall is provided with a plurality of ventilation hole matrices. The housing 10 defines a longitudinal direction L along its length, a width direction W along its width, and a height direction H along its height.

At the front end and rear end of the main body portion 11 of the housing 10 in the longitudinal direction L, the outer surfaces in the width direction W are respectively provided with lateral openings 111 extending downward from the upper edge in the height direction H. In an embodiment, there are four lateral openings 111 in total, with two of the lateral openings 111 located at the front end and the other two lateral openings 111 located at the rear end of the main body portion 11. The middle portion of each lateral opening 111 in the height direction H is respectively provided with a semi-circular protrusion 111A protruding into the lateral opening 111 along the longitudinal direction L. The protrusion 111A includes at least one through-hole for components such as screws to pass through. In addition, a baffle 111B, which is recessed via two right-angle bends toward the inner side in the width direction W, is provided below the semi-circular protrusion 111A in the height direction H. Through-holes are provided on the baffle 111B for components such as screws to pass through to fix the cover plate 12 to the outer side in the width direction W thereof. The surface where the through-holes of the baffle 111B are located extends from a periphery of the lateral opening 111 of the housing 10 through two right-angle bends and is substantially parallel to the cover plate 12. In an embodiment, the semi-circular protrusion 111A and the baffle 111B are offset from each other along the width direction W. Specifically, the baffle 111B is recessed inward relative to the semi-circular protrusion 111A, thereby defining a space for receiving the cover plate 12.

In addition, the cover plate 12 is embedded in each lateral opening 111, and the shape of the cover plate 12 matches each lateral opening 111 to close the lateral opening 111. The middle portion of the cover plate 12 in the height direction H is provided with a semi-circular notch 121 having a shape complementary to the semi-circular protrusion 111A. The upper portion of the cover plate 12 in the height direction H is provided with a locking hole for components such as screws to pass through, used for simultaneously fixing the grounding bar 50 to the inner side of the main body portion 11 in the width direction W. The lower portion of the cover plate 12 in the height direction H includes a wider tube hole 122 for pipelines to pass through, and a plurality of locking holes are respectively provided on both sides of the tube hole 122. After the cover plate 12 is embedded in the lateral opening 111, its inner surface in the width direction W abuts against the baffle 111B and is fixed thereto via screws, and the outer surface of the cover plate 12 in the width direction W is substantially flush with the outer surface of the main body portion 11 in the width direction W.

Both the front and rear ends of the main body portion 11 of the housing 10 in the longitudinal direction L have fixing arm portions 112 further extending along the longitudinal direction L, and a support plate 13 is connected to the lower opening between the two fixing arm portions 112 in the height direction H. Both the fixing arm portions 112 and the support plate 13 are respectively used for fixing with external structures.

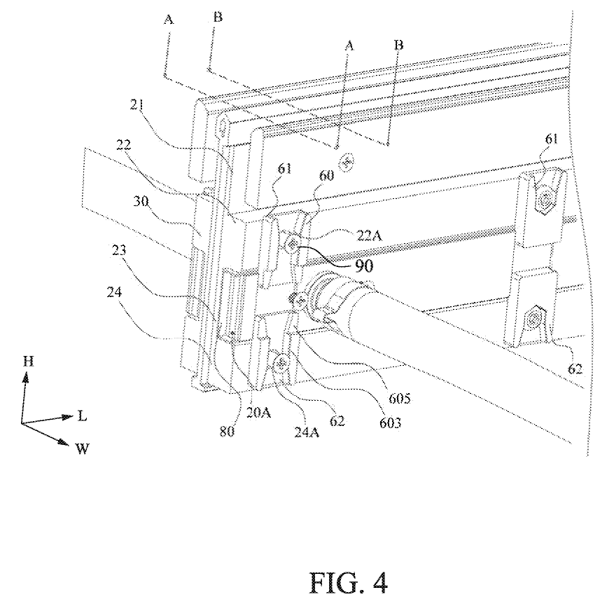

The design of the busbar 20 is explained below. Referring to FIG. 3 and FIG. 4, it can be seen from the figures that the busbar 20 (also referred to as a first busbar) is integrally formed. The polarity of the busbar 20 is opposite to that of the busbar 30. The busbar 20 has a head portion 21, a shoulder 22, a waist 23, and a base 24 sequentially connected along the height direction H. Each of the head portion 21, the shoulder 22, the waist 23, and the base 24 is in a rectangular bar shape, and their inner surfaces in the width direction W collectively form an inner coplanar surface to abut against the surface of the insulating member 40. The thickness of the waist 23 in the width direction W is less than the thicknesses of the shoulder 22 and the base 24, so that the shoulder 22, the waist 23, and the base 24 together define and form a rectangular receiving slot 20A extending along the longitudinal direction L.

The side surfaces of the shoulder 22 and the base 24 in the width direction W are respectively provided with a plurality of through-holes penetrating through their inner and outer surfaces, referred to as fixing holes 22A, 24A. The fixing holes 22A, 24A are used for embedding the fastening members 60 or components such as screws. The fixing hole 22A located at the shoulder 22 may be referred to as an upper fixing hole 22A, and the fixing hole 24A located at the base may be referred to as a lower fixing hole 24A.

The head portion 21 and the shoulder 22 define an L-shaped accommodation space. The grounding bar 50 is fixed to the housing 10 and is suspended within the L-shaped accommodation space.

The design of the busbar 30 is explained below. The design of the busbar 30 substantially corresponds to and is identical to that of the busbar 20, and is arranged in a mirror-image manner.

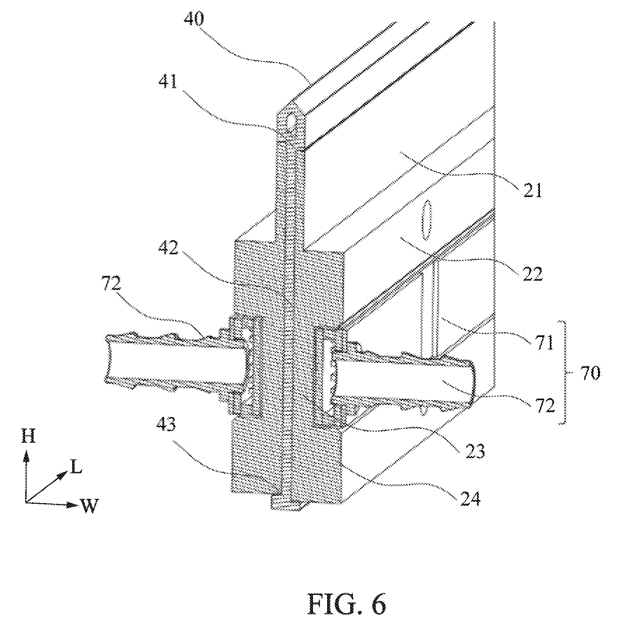

The design of the insulating member 40 is explained below. Referring to FIG. 6, the insulating member 40 is integrally formed of a high-resistance material, and most of it extends uniformly along the longitudinal direction L. The term "uniformly" means that the shape of each cross-section along the longitudinal direction L is substantially the same. The insulating member 40 has a top portion 41, a middle portion 42, and a base portion 43 sequentially from top to bottom. The top portion 41 is a hollow tubular shape extending along the longitudinal direction L, and its cross-sectional shape is a gable-roof shape. The lower edge surface of one side of the top portion 41 in the width direction W is higher in the height direction H, while the other side in the width direction W is lower, so that the two busbars 20, 30 form a displacement and a height difference. The middle portion 42 is a vertical plate used to isolate the busbar 20 and the busbar 30 to prevent a short circuit between the two. In the width direction W, the left and right sides of the base portion 43 respectively extend toward both sides to contact and support the busbar 20 and the busbar 30, respectively. Similarly, in the width direction W, the left side of the base portion 43 is thicker while the right side is thinner, allowing the busbar 20 and the busbar 30 to form a displacement and a height difference. Referring to FIG. 4, the length of the insulating member 40 in the longitudinal direction L is greater than the lengths of the busbars 20, 30; that is, parts of its front and rear ends in the longitudinal direction L will protrude from the two busbars 20, 30.

The design of the grounding bar 50 is explained below. Referring to FIG. 2, the two grounding bars 50 can be made of a metal material and are fixed to the inner sides of both sides of the main body portion 11 by a plurality of screws passing through the cover plate 12 and the main body portion 11. In an embodiment, this configuration achieves a "multi-in-one" objective, significantly reduces the number of screws required for rack assembly, lowers manufacturing costs, and shortens maintenance time.

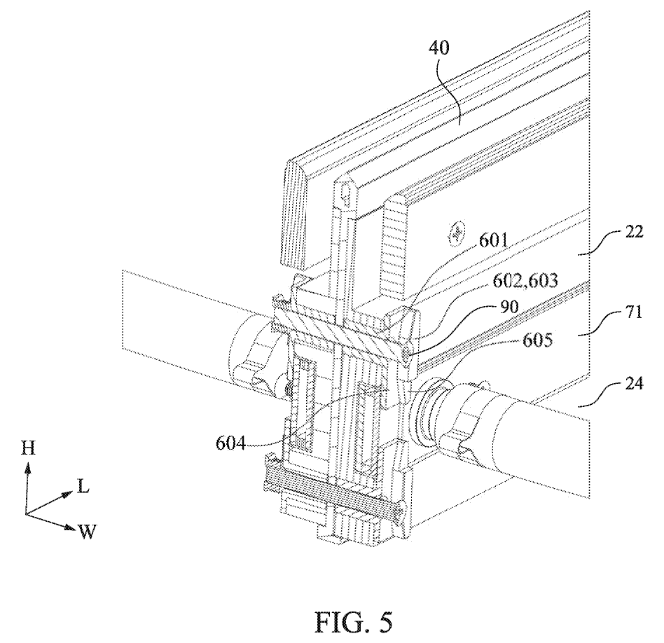

The design of the fastening member 60 is explained below. Referring to the design in FIG. 4, it can be seen that a plurality of fastening members 60 are fixed to the upper fixing holes 22A of the shoulders 22 and the lower fixing holes 24A of the bases 24 of the busbars 20, 30 via components such as screws. The fastening member 60 fixed to the shoulder can be referred to as an upper fastening member 61, and the fastening member 60 fixed to the base 24 can be referred to as a lower fastening member 62. Referring to FIG. 5, the fastening member 60 is integrally formed of an insulating material and can be roughly divided into two parts: a horizontal portion 601 and a vertical portion 602. Referring to FIG. 5, the horizontal portion 601 has a hollow conduit penetrating through two side surfaces of the busbar 20 in the width direction W, allowing components such as screws to enter and pass through.

Specifically, the rack busbar assembly of the present invention achieves interconnected securing (or fixing) of the busbars 20, 30 and the insulating member 40 by passing at least one fastener 90 (e.g., a screw) through hollow conduits thereof. Particularly, the fastener 90 simultaneously passes through the horizontal portion 601 of the fastening member 60 during the locking process. In an embodiment, by this design, the assembly process is simplified via a 'multi-in-one' locking path, while ensuring that the thermal conductive elements 71 fit tightly and stably within the receiving slots 20A, thereby enhancing structural reliability and heat conduction efficiency. Furthermore, this locking structure ensures that various components maintain excellent geometric stability under stress, effectively preventing displacement of the thermal conductive element 71 due to vibration or thermal expansion and contraction.

The vertical portion 602 is disposed perpendicular to the horizontal portion 601, and the inner surface of the vertical portion 602 of each fastening member 60 in the width direction W flatly abuts against the outer side surfaces of the shoulder 22 and the base 24 in the width direction W. Taking the upper fastening member 61 at the upper fixing hole 22A as an example, its upper and lower sides in the height direction H respectively extend outward along the height direction H and form a cantilever structure to at least partially cover the receiving slot 20A. Structurally, the term 'cantilever structure' as used herein refers to a configuration where a portion of the vertical portion 602 extends outwardly along the height direction H from its connection with the horizontal portion 601. This extending portion is supported at its proximal end and projects over the opening of the receiving slot 20A, characterized in that its distal end is substantially unsupported from underneath to allow it to retain the thermal conductive element 71. The cantilever structure is used to block or contact the thermal conductive element 71 in the thermal conductive element group 70, thereby preventing the thermal conductive element 71 from detaching from the receiving slot 20A in the width direction W. The lower fastening member 62 may have a similar cantilever structure extending upward.

More specifically, the horizontal portion 601 is used for the fastener 90 to pass through to achieve positioning, while the vertical portion 602 is stably disposed at the opening of the receiving slot 20A by the locking action to block the thermal conductive element 71 from detaching from the receiving slot 20A.

In one embodiment, the fastening member 60 is made of an insulating material. As shown in FIG. 5, the horizontal portion 601 is interposed between the fastener 90 and the busbars 20, 30 to electrically isolate the fastener 90 from the busbars 20, 30. This configuration prevents an electrical connection between the two busbars 20, 30 through the metallic fastener 90.

Referring to FIG. 5, a portion of the upper fastening member 61 also protrudes upward from the shoulder 22 in the height direction H and forms a cantilever structure. In addition, the design of the fastening member 60 at the lower fixing hole 24A is substantially the same as the aforementioned design, also having a portion that forms a cantilever structure to prevent the thermal conductive element 71 from detaching from the receiving slot 20A in the width direction W. In an embodiment, the positions of the upper fixing hole 22A and the lower fixing hole 24A are the same in the longitudinal direction L; thus, upper fastening member 61 and the lower fastening member 62 are vertically aligned in the height direction H to form a gap therebetween, through which a portion of the thermal conductive element 71 is exposed. In an embodiment, this configuration provides a space for visual confirmation of the assembly status, increases the heat dissipation area of the thermal conductive element 71 in contact with air, and maintains the lateral physical limiting function of the vertical portion for the thermal conductive element 71. The left and right edges of the vertical portion 602 of each fastening member 60 in the longitudinal direction L can abut against the walls of the retaining grooves 713 on the surface of the thermal conductive element 71 to prevent the thermal conductive element 71 from sliding along the longitudinal direction L. In an embodiment, this configuration effectively locks the longitudinal position of the thermal conductive element 71 and prevents it from shifting during vertical installation or in an environment with operating vibrations.

The design of the outer surface of the fastening member 60 in the width direction W varies depending on its position. The following uses the fastening member 60 located at the cover plate 12 or the lateral opening 111 and the remaining fastening members 60 not located at the lateral opening 111 as examples for explanation.

Referring to FIG. 5, the fastening member 60 corresponding to the lateral opening 111 includes two blocks 603 disposed on an outer surface in the width direction W. The two blocks 603 are spaced apart in the longitudinal direction L to define a guiding groove 604 therebetween. Along the height direction H from top to bottom, the guiding groove 604 sequentially tapers, maintains width in the middle, and widens at the lower section. Structurally, the guiding groove 604 includes a tapered segment, a constant-width segment, and a flared segment corresponding to the variation in width from top to bottom. In an embodiment, this configuration guides the fastener 90 to cut into position accurately and rapidly. The hollow conduit of the fastening member 60 is located at the middle section. The two blocks 603 are bounded by the portion cantilevered over the rectangular receiving slot 20A, and a stepped notch 605 is formed at the lower section. That is, the thickness of the cantilevered portion of the block 603 is thinner but still protrudes relative to the bottom of the guiding groove 604. In this way, the space reserved by the stepped notch 605 can accommodate the baffle 111B which is recessed after being bent toward the inner side in the width direction W, thereby avoiding geometric interference between the fastening member 60 and the housing 10. In an embodiment, this configuration maximizes internal space utilization and eliminates geometric interference between components, while maintaining a flat appearance of the housing and ensuring that the assembly can be smoothly installed in narrow rack spaces. In contrast, for the fastening members 60 not located at the lateral opening 111, the upper section tapers downward to merge at the middle section. The lower section of these fastening members 60 maintains a uniform thickness that is consistent with the thickness of the block 603 at the upper section, thereby forming a continuous cantilever structure without the guiding groove 604 or the stepped notch 605.

Referring to FIG. 5, both the busbar 30 and the insulating member 40 are provided with hollow conduits penetrating through two side surfaces in the width direction W, and the hollow conduits of the busbar 20, the busbar 30, and the insulating member 40 are aligned. During assembly, a fastener 90 can be used to pass through the hollow conduits of the busbar 20, the busbar 30, and the insulating member 40 and be connected via a nut to clamp the two busbars 20, 30 therein.

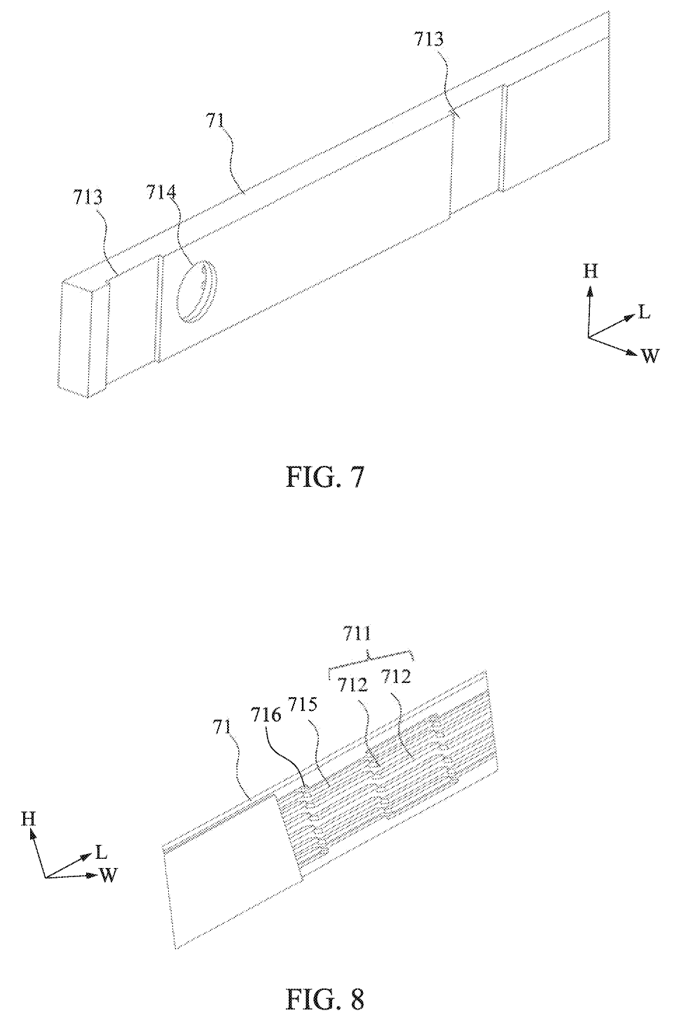

The design of the two thermal conductive element groups 70 is explained below. Referring to FIG. 6 and FIG. 7, the two thermal conductive element groups 70 respectively include a thermal conductive element 71 and two nozzle-shaped connectors 72 at both front and rear ends in the longitudinal direction L.

The thermal conductive elements 71 are respectively liquid-cooled plates extending along the longitudinal direction L. However, each thermal conductive element 71 can also be a heat pipe or a thermal conductive block (e.g., solid metal body) with high thermal conductivity. In an embodiment where the thermal conductive element 71 is configured as a liquid-cooled plate or a thermal conductive block, the interior thereof defines a main flow channel 715 and a plurality of fins 712 for heat exchange. On an outer side plate of the thermal conductive element 71 in the width direction W, a plurality of cut shallow grooves, or retaining grooves 713, are provided. The retaining grooves 713 are disposed corresponding to the fastening members 60. The fastening members 60 are embedded in the retaining grooves 713 so that their groove walls can abut against the side edges of the fastening members 60, thereby preventing the thermal conductive elements 71 from sliding along the longitudinal direction L in the receiving slots 20A. The formation of the retaining grooves 713 can be achieved by the aforementioned cutting, or by pasting blocks of thermally conductive or insulating material on the surface of the thermal conductive element 71 to form the retaining grooves 713 therebetween, thereby reducing costs.

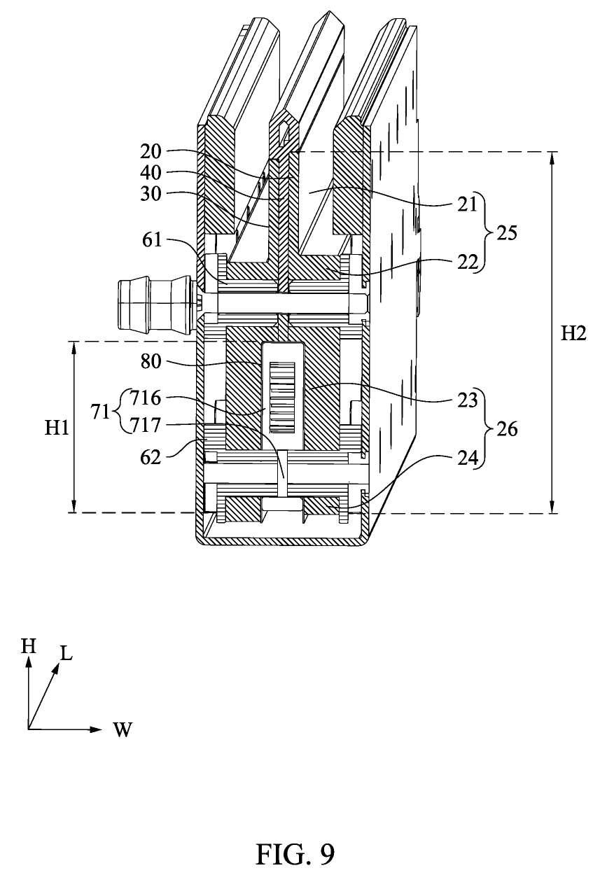

Referring to FIG. 8, the thermal conductive element 71 has a main flow channel 715 extending along the longitudinal direction L. If the outer side plate of the thermal conductive element 71 in the width direction W is opened, it can be seen that the main flow channel 715 is composed of a plurality of wide flow sections and narrow flow sections connected and arranged alternately. Specifically, these wide flow sections and narrow flow sections are fluidly communicating with each other, thereby allowing the cooling fluid to flow continuously through the main flow channel 715 while undergoing pressure and velocity changes to enhance heat exchange. The main flow channel 715 communicates with external pipelines only through inlet and outlet ports 714 at both front and rear ends in the longitudinal direction L. A plurality of fin groups 711 are formed between an inner side plate and the outer side plate of the thermal conductive element 71 in the width direction W. Each fin group 711 includes a plurality of fins 712, and each fin 712 and another fin 712 or an internal surface of the thermal conductive element 71 respectively define a smaller sub-flow channel.

Furthermore, the flow channel corners, specifically where the main flow channel 715 transitions from a wide section to a narrow section, are provided with a curved guide structure 716. Structurally, the curved guide structure 716 is formed by a transition surface (such as a rounded fillet or a chamfered bevel) extending between the wall surfaces of the sections.

In an embodiment, this curved guide structure 716 contributes to several technical advantages. For instance, it helps to reduce flow resistance and pressure drop by guiding the fluid smoothly through section transitions, minimizing flow separation and ineffective vortices compared to right-angled turns. Additionally, the design is intended to improve heat exchange efficiency by reducing flow dead zones where bubbles or impurities might accumulate, ensuring that the cooling fluid uniformly covers the fin surfaces of the fins 712. Furthermore, the transition surface helps to reduce stress concentrations caused by fluid pressure, potentially enhancing the structural durability of the thermal conductive element 71 and mitigating erosion-corrosion at the flow edges.

In an embodiment, an inner surface of the outer side plate of the thermal conductive element 71 in the width direction W can be physically connected (e.g., combined through welding or an integral molding process) with the fins 712 to strengthen the heat conduction path. In another embodiment, the inner surface of the outer side plate of the thermal conductive element 71 in the width direction W may also not be connected to the fins 712 (i.e., maintaining a tiny gap therebetween) to facilitate assembly or allow for differences in thermal expansion between different materials. Furthermore, regarding the geometric arrangement of the fins 712, a surface of the fin 712 on the longitudinal direction L side (i.e., the surface facing the fluid inflow direction) can be disposed perpendicular to a bottom surface of the main flow channel 715; alternatively, the surface of the fin 712 on the longitudinal direction L side can also maintain an oblique angle (i.e., inclined arrangement) relative to the bottom surface of the main flow channel 715, thereby guiding the fluid to deflect in a specific direction or generate more intense high-temperature boundary layer disturbances.

An outlet of each sub-flow channel in the fin group 711 is aligned with a surface of a downstream fin 712 along the longitudinal direction L. Such an arrangement directs fluid exiting the sub-flow channel to impinge on the surface of the downstream fin 712, thereby altering the flow direction and dissipating kinetic energy. In an embodiment, the impact of the fluid against the downstream fins 712 promotes turbulent flow and increases the residence time of the coolant on the fin surfaces, thereby enhancing the overall heat dissipation performance.

A transversely disposed connector 72 is provided on a surface of the thermal conductive element 71 in the width direction W respectively at the front and rear ends in the longitudinal direction L. One end of the connector 72 is welded to the inlet/outlet port 714 of the thermal conductive element 71, and the other side communicates with a pipeline via a snap ring. In use, the connector 72 can obtain cooling fluid from an external pipeline and input it into the main flow channel 715 inside the thermal conductive element 71.

The design of the thermal conductive insulating material layer 80 is explained below. Referring to FIG. 4, the thermal conductive insulating material layer 80 is made of a material that is electrically insulating and has good thermal conductivity, such as a thermal silicone sheet. However, if necessary, it may also be formed by a thermal grease or a combination of multiple material layers respectively having thermal conductive and insulating properties. The thermal conductive insulating material layer 80 is disposed between the busbars 20, 30 and the respective thermal conductive elements 71 for conducting thermal energy of the busbars to the surface of the thermal conductive element 71 while ensuring that the thermal conductive elements 71 and the busbars 20, 30 are electrically insulated to each other. The thermal conductive insulating material layer 80 has C-shaped-section and substantially covers the inner surfaces of the receiving slot 20A. In an embodiment, this configuration is designed to provide electrical insulation between the high-current path and the thermal conductive element 71, thereby preventing current leakage.

In application, cooling fluid enters the internal main flow channel 715 from one end of the thermal conductive element 71 through the connector 72 from a pipeline. After the cooling fluid flows along the longitudinal direction L and takes away thermal energy from the busbar 20, it leaves from the connector 72 at the other end of the thermal conductive element 71 to complete the cooling process.

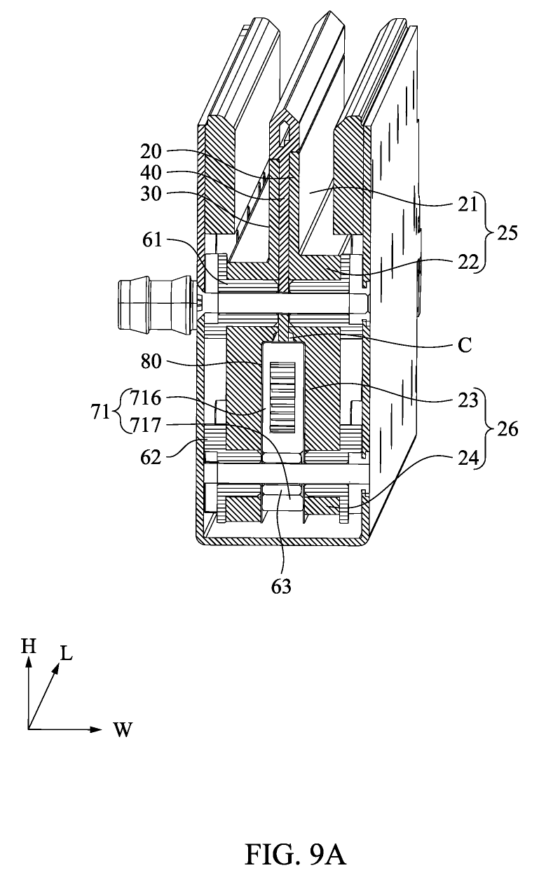

Referring to FIG. 9, a second embodiment of the rack busbar assembly A is illustrated. Only the main differences from specific embodiments will be described below; parts that are not mentioned are the same as or similar to those in the first embodiment. The following describes the design of the second embodiment. In the present embodiment, the structure of the busbars 20, 30 and the arrangement of the thermal conductive element 71 are modified compared to the first embodiment to form a sandwich-type configuration.

Specifically, regarding the definition of the busbars 20, 30, each of the busbars 20, 30 generally comprises an upper portion 25 and a lower portion 26 connected to the upper portion 25 along the height direction H. The upper portion 25 includes the head 21 and the shoulder 22, while the lower portion 26 includes the waist 23 and the base 24. Unlike the first embodiment where two thermal conductive elements are respectively disposed on outer sides of the busbars 20, 30, in the present embodiment, a single thermal conductive element 71 is provided and disposed between the lower portions 26 of the two busbars 20, 30.

The insulating member 40 is disposed between the upper portions 25 of the two busbars 20, 30 to electrically isolate the busbars. In an embodiment, the bottom end of the insulating member 40 has an I-shaped cross-section, rather than having platforms extending in the width direction W or a T-shaped base as shown in FIG. 6 of the first embodiment. Specifically, the insulating member 40 in the present embodiment has a shortened length that terminates at the upper portions 25 (specifically, at the shoulders 22) and comes into contact with a top surface of the thermal conductive insulating material layer 80 described later. The insulating member 40 does not extend into the space between the lower portions 26. That is, no insulating member 40 is present between the waists of the two busbars 20, 30, and no insulating member 40 is present between the bases 24 of the two busbars 20, 30. Furthermore, the bases 24 at the bottom do not converge inward but maintain the same distance as the waists 23. In other words, the two bases 24 are spaced apart from each other relative to the shoulders 22.

The thermal conductive element 71 comprises a hollow portion 716 and a connecting portion 717 connected to the hollow portion 716 along the height direction H. The hollow portion 716 corresponds to the upper section defined in the claims, and the connecting portion 717 corresponds to the lower section defined in the claims.

The hollow portion 716 defines the liquid flow channel therein. In an embodiment, to facilitate manufacturing and prevent liquid leakage, the hollow portion 716 comprises a main body and a side cover plate made of the same material (e.g., aluminum or copper), wherein the side cover plate may be welded to the left or right side of the main body to seal the liquid flow channel laterally. This configuration optimizes the forming process of the hollow liquid flow channel. The connecting portion 717 is a solid block structure located below the hollow portion 716.

A thermal conductive insulating material layer 80 is disposed between the thermal conductive element 71 and the busbars 20, 30. In an embodiment, as shown in FIG. 9, the thermal conductive insulating material layer 80 has an inverted U-shaped cross-section. Specifically, the thermal conductive insulating material layer 80 covers a top end of the hollow portion 716 (i.e., the upper section) and extends downward along lateral sides of both the hollow portion 716 and the connecting portion 717 (i.e., the lower section) of the thermal conductive element 71. This configuration electrically isolates the thermal conductive element 71 from the lower portions 26 of the busbars 20, 30 while allowing heat transfer. Furthermore, the fastener 90 passes through lateral portions of the thermal conductive insulating material layer 80 at a position corresponding to the connecting portion 717. These lateral portions correspond to the structural sides of the inverted U-shape. In an embodiment, the thermal conductive insulating material layer 80 is a thermal pressing film made of polyethylene terephthalate (PET).

Regarding the fastening mechanism, the lower portions 26 of the busbars 20, 30 clamp the connecting portion 717 (i.e., the lower section) of the thermal conductive element 71. The lower fastening member 62 is disposed at the lower portions 26 and is configured to receive the fastener 90 to secure the clamping assembly. In an embodiment, the lower fastening member 62 has a hollow conduit penetrating through the lower portion 26 of the busbar in the width direction W and extending into a through hole formed in the solid connecting portion 717 of the thermal conductive element 71, allowing components such as the fastener 90 to enter and pass through. In an embodiment, the lower fastening member 62 comprises two separate parts installed from opposite sides in the width direction W. The two parts extend into the through hole of the connecting portion while maintaining a gap in the width direction W. Although the fastener 90 is not explicitly shown in the cross-sectional view of FIG. 9, it is understood that the fastener 90 passes through the lower portions 26 of the busbars 20, 30 and the lower fastening member 62 to secure the assembly. Since the fastener 90 is separated from the two busbars 20, 30 and the thermal conductive element 71 by the electrically insulating lower fastening member 62, the fastener 90 is electrically isolated from the two busbars 20, 30.

In an embodiment, the arrangement of the fastening members 61, 62 along the longitudinal direction L may vary. For example, the upper fastening member 61 (securing the upper portions 25) and the lower fastening member 62 (securing the lower portions 26) are not necessarily aligned in the same vertical cross-section. They may be disposed at staggered positions along the longitudinal direction L to optimize structural strength and space utilization.

In an embodiment, the configuration facilitates a compact design by utilizing the space between the busbars 20, 30 for the single thermal conductive element 71. The ratio of the maximum height H1 of the thermal conductive element 71 to the maximum height H2 of the busbars 20, 30 is configured to be between 40% and 80%, ensuring sufficient heat exchange area while maintaining structural stability of the busbars 20, 30. Taking the busbar 20 as an example, the maximum height H2 refers to the maximum straight-line distance along the height direction H from any point of the head 21 to any point of the base 24 in any cross-section along the longitudinal direction L. Specifically, in the present embodiment, the maximum height H2 is approximately 73 mm, and the maximum height H1 of the thermal conductive element 71 is approximately 34 mm. That is, the height of the thermal conductive element 71 is approximately 46% of the maximum height of the busbar 20.

In an embodiment, referring to FIG. 9A, a variation of the fastening mechanism of the second embodiment is illustrated. In this variation, the two separate parts of the lower fastening member 62 disposed at the lower portions 26 of the busbars 20, 30 do not extend into the through hole provided in the connecting portion 717 of the thermal conductive element 71. Instead, an insulating sleeve 63 is additionally provided and disposed within the through hole of the connecting portion 717. The insulating sleeve 63 serves as a transitional element between the two separate parts of the lower fastening member 62 in the width direction W. When the fastener 90 passes through the assembly, it passes through the lower fastening member 62 and the insulating sleeve 63. This configuration similarly ensures that the fastener 90 is completely electrically isolated from the two busbars 20, 30 and the thermal conductive element 71, thereby maintaining electrical safety.

Furthermore, in this variation, a bottom end of the insulating member 40 contacts the thermal conductive insulating material layer 80, and lateral sides of the bottom end of the insulating member 40 are spaced apart from the two busbars 20, 30 to define a clearance C therebetween. In an embodiment, the configuration facilitates increasing a creepage distance between the busbars 20, 30 and other conductive components, and simultaneously reserves a tolerance space for assembly to accommodate manufacturing deviations.

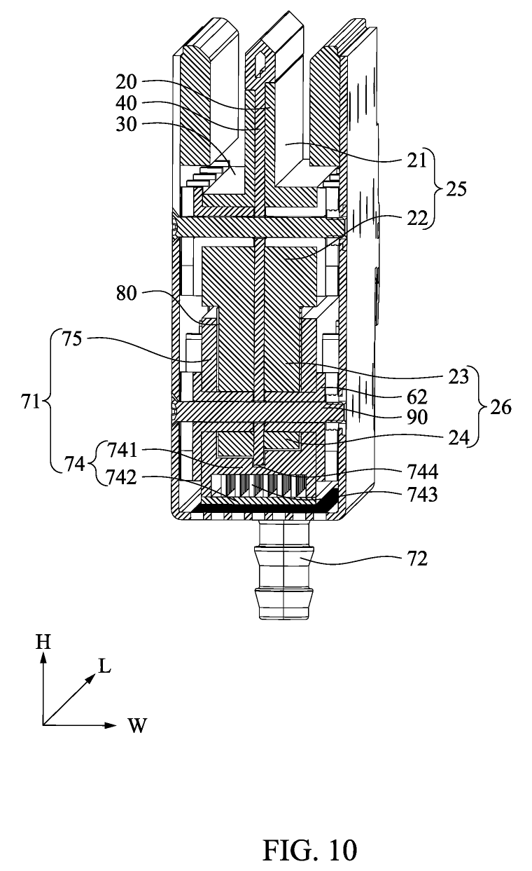

Referring to FIG. 10, a third embodiment of the rack busbar assembly A is illustrated. Only the main differences from specific embodiments will be described below; parts that are not mentioned are the same as or similar to those in the first embodiment. The following describes the design of the third embodiment. In the present embodiment, instead of being disposed between the busbars, the thermal conductive element 71 is disposed surrounding the lower portions 26 of the two busbars 20, 30. Unlike the first embodiment, the third embodiment comprises only a single thermal conductive element 71, which includes only a single liquid flow channel.

Specifically, regarding the geometry of the busbars 20, 30, a thickness of the lower portion 26 (including the waist 23 and the base 24) of each busbar 20, 30 in the width direction W is less than a thickness of the upper portion 25 (including the head 21 and the shoulder 22), wherein the waist 23 and the base 24 have the same thickness, and the shoulder 22 is thicker than the waist 23 and the base 24. This thickness difference defines a stepped space configured for accommodating components of the thermal conductive element 71. Meanwhile, an outer surface of the shoulder 22 of the busbar 20 and an outer surface of the thermal conductive element 71 are flush with each other and located on the same virtual surface.

The thermal conductive element 71 comprises a liquid cooling plate 74 defining the liquid flow channel therein, and two extension walls 75 extending upward from opposite lateral sides of the liquid cooling plate 74 to form a generally C-shaped structure. The C-shaped structure wraps around bottom surfaces and outer lateral sides of the lower portions 26 of the two busbars 20, 30. In an embodiment, the liquid cooling plate 74 comprises a body portion 741 having a slot 743 and a cover plate 742. The cover plate 742 is welded to an opening of the slot 743 and encloses the slot 743 to serve as a main flow channel 715 for the cooling liquid, thereby forming the liquid flow channel. In an embodiment, the body portion 741 and the cover plate 742 may be made in the same material. The internal design of the flow channel may be the same as that of the first embodiment. This two-piece design of the liquid cooling plate 74 optimizes the manufacturing process of the internal flow channel, and the solid metal extension walls 75 and the body portion 741 are integrally formed. Furthermore, the internal flow channel of the thermal conductive element 71 communicates with the outside via a plurality of connectors 72 (e.g., two nozzle-shaped connectors) spaced apart along the longitudinal direction L and disposed on the cover plate 742 to exchange the cooling liquid. Correspondingly, a bottom wall of the housing 10 is provided with relatively large openings at two longitudinal ends along the longitudinal direction L, allowing the inlet and outlet connectors 72 to respectively pass therethrough.

To ensure electrical insulation while maintaining thermal conductivity, two separate thermal conductive insulating material layers 80 are provided. Unlike the single inverted U-shaped layer in the second embodiment, the two separate thermal conductive insulating material layers 80 are L-shaped. They are sandwiched between the lateral surfaces of the lower portions 26 of the two busbars 20, 30 and inner lateral surfaces of the two extension walls 75, and also between the bottom surfaces of the lower portions 26 of the two busbars 20, 30 and a top surface of the liquid cooling plate 74 of the thermal conductive element 71.

The insulating member 40 is disposed between the two busbars 20, 30 to electrically isolate the busbars 20, 30. In an embodiment, the liquid cooling plate 74 comprises a positioning groove 744 formed on the top surface thereof. A bottom end of the insulating member 40 extends downward beyond the bottom surfaces of the lower portions 26 and is engaged in the positioning groove 744. Bounded by the positioning groove 744, the top surfaces on the left and right sides of the liquid cooling plate 74 have different heights. This structural engagement ensures that the insulating member 40 is stably positioned between the busbars 20, 30 and prevents lateral displacement.

Regarding the fastening mechanism, the fastener 90 passes through the lower portion 26 of the busbar 20, 30, the lower fastening member 62, and the two extension walls 75 of the thermal conductive element 71 to secure the assembly. The electrically insulating lower fastening member 62 ensures that the fastener 90 is electrically isolated from the busbars 20, 30.

In an embodiment, the configuration facilitates a highly integrated structure by utilizing the C-shaped thermal conductive element 71 to wrap the busbars 20, 30. This not only provides structural support from the bottom but also maximizes the heat exchange area around the lower portions 26. Specifically, besides the body portion 741 of the liquid cooling plate 74, the heat of the busbars 20, 30 can be more effectively transferred via the extension walls 75 to the liquid cooling plate 74 and carried away by the cooling liquid therein, thereby effectively improving the cooling efficiency for the rack busbar assembly A.

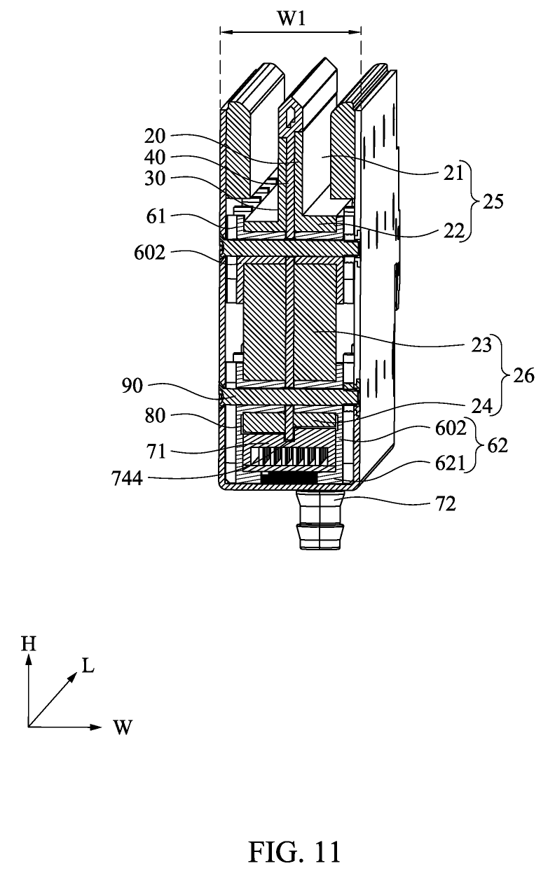

As a further improvement of the third embodiment, the design of a fourth embodiment is described below. Referring to FIG. 11, a fourth embodiment of the rack busbar assembly A is illustrated. Only the main differences from specific embodiments will be described below; parts that are not mentioned are the same as or similar to those in the third embodiment. In the present embodiment, the thermal conductive element 71 is similarly disposed below the lower portions 26 of the two busbars 20, 30. However, the fourth embodiment differs from the third embodiment in that the two metal extension walls 75 are entirely omitted. Correspondingly, the two busbars 20, 30 (specifically, the lower portions 26) are respectively thickened to compensate for the omitted space.

At the same time, in the width direction W, left and right sidewalls of the housing 10 tightly clamp the two busbars 20, 30, the insulating member 40, and other components securely therein via the upper fastening member 61 and the lower fastening member 62. In an embodiment, a maximum width W1 of the housing 10 is equal to the sum of thicknesses of the two sidewalls of the housing 10, maximum thicknesses of portions of the two upper fastening members 61 exposed from the two busbars (i.e., the vertical portions 602), maximum thicknesses of the two busbars 20, 30, and a maximum thickness of a middle portion 42 of the insulating member 40.

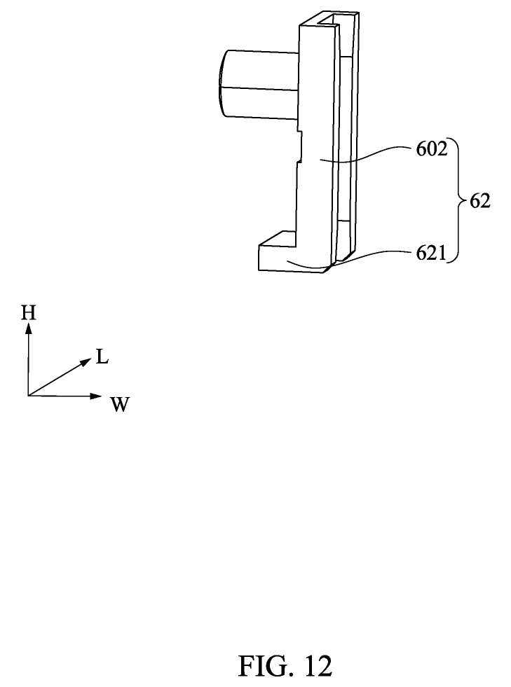

To maintain the position of the thermal conductive element 71 under the condition where the metal extension walls 75 are omitted, the lower fastening member 62 is structurally modified. Specifically, as further illustrated in the isolated view of FIG. 12, the lower fastening member 62 comprises a vertical portion 602 extending along the height direction H, and the vertical portion 602 abuts against the lower portion 26 of the busbars 20, 30. The lower fastening member 62 is L-shaped. That is, a bending platform 621 extends from a lower part of the vertical portion 602 to a bottom surface of the thermal conductive element 71 to form an L-shaped structure. The bending platform 621 is configured to support the bottom surfaces of the left and right sides of the thermal conductive element 71 in the width direction W and suspend the thermal conductive element 71 above a bottom of the U-shaped housing 10.

In an embodiment, the lower fastening member 62 clamps lateral sides of the thermal conductive element 71 to restrict movement of the thermal conductive element 71 in the width direction W. Also, similar to the third embodiment, two separate thermal conductive insulating material layers 80 are respectively sandwiched between the bottom surfaces of the lower portions 26 of the two busbars 20, 30 and a top surface of the thermal conductive element 71.

In an embodiment, the configuration facilitates a more concise and simpler structural design while achieving the same cooling effect as the third embodiment. The L-shaped lower fastening member 62 effectively supports and positions the single thermal conductive element 71 without requiring additional metal extension walls, thereby reducing manufacturing complexity and material costs. Furthermore, suspending the thermal conductive element 71 above the bottom of the housing 10 ensures stable positioning and reliable electrical isolation.

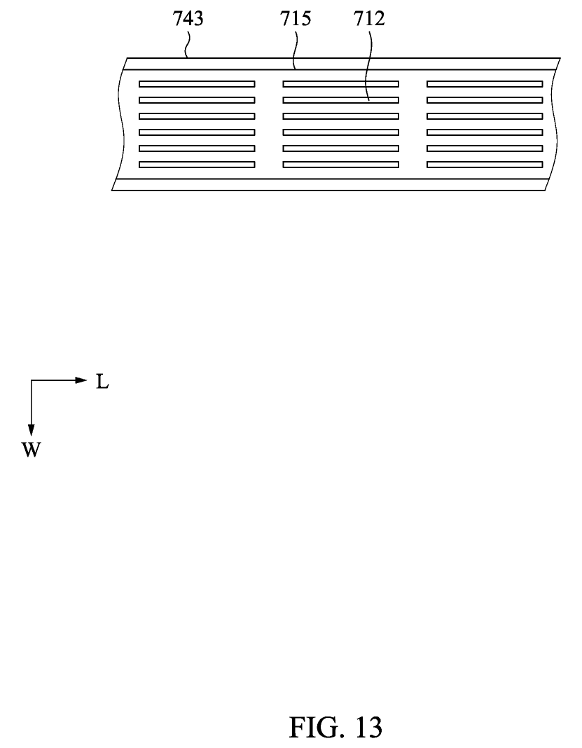

Referring to FIG. 13, a variation of the internal design of the liquid flow channel of the thermal conductive element 71 is illustrated. In an embodiment, the internal design of the liquid flow channel applicable to the third and fourth embodiments (as respectively shown in FIGS. 10 and 11) may differ from that of the first embodiment shown in FIG. 8. Specifically, the main flow channel 715 may not comprise the combination of alternating wide channel sections and narrow channel sections. Instead, the plurality of fins 712 disposed in the main flow channel 715 are aligned in straight rows along the longitudinal direction L. In this configuration, each fin 712 is longitudinally aligned with its downstream fin 712. Consequently, the sub-flow channels formed between the fins 712 extend straightly, such that the cooling liquid flowing out of the outlet of a sub-flow channel smoothly enters the downstream sub-flow channel without hitting a sidewall of the downstream fin 712. In an embodiment, the configuration facilitates a significant reduction in fluid resistance, allowing for a smoother flow of the cooling liquid and optimizing the pressure drop across the single thermal conductive element 71.

The above are only exemplary embodiments of the present invention and do not limit the scope of the patent of the present invention. Any equivalent structural transformations made under the technical concept of the present invention using the contents of the description and drawings of the present invention, or direct/indirect applications in other related technical fields, are included in the scope of patent protection of the present invention.

What is claimed is:

1. A rack busbar assembly, comprising:
a housing;
two busbars disposed within the housing and extending along a longitudinal direction, each of the two busbars comprising an upper portion and a lower portion connected to the upper portion along a height direction;
an insulating member disposed between the upper portions of the two busbars to electrically isolate the two busbars;
a thermal conductive element defining a liquid flow channel therein, wherein the thermal conductive element is disposed adjacent to the lower portions of the two busbars;
a fastening member disposed at the lower portions of the two busbars; and
a fastener passing through the lower portions of the two busbars and the fastening member to secure the thermal conductive element relative to the two busbars.

2. The rack busbar assembly of claim 1, wherein the fastening member is made of an insulating material and electrically isolates the fastener from the two busbars.

3. The rack busbar assembly of claim 1, wherein the thermal conductive element is disposed between the lower portions of the two busbars.

4. The rack busbar assembly of claim 3, wherein the insulating member terminates at the upper portions of the two busbars and has an I-shaped cross-section at a bottom end thereof.

5. The rack busbar assembly of claim 3, wherein the thermal conductive element comprises an upper section and a lower section connected to the upper section, the upper section being hollow and defining the liquid flow channel, and the lower section being a solid connecting portion.

6. The rack busbar assembly of claim 5, wherein the fastener passes through the lower portions of the two busbars and the solid connecting portion of the thermal conductive element.

7. The rack busbar assembly of claim 5, further comprising:
a thermal conductive insulating material layer having an inverted U-shaped cross-section covering an upper end of the thermal conductive element, wherein the fastener passes through the thermal conductive insulating material layer.

8. The rack busbar assembly of claim 7, wherein a bottom end of the insulating member contacts the thermal conductive insulating material layer, and lateral sides of the bottom end of the insulating member are spaced apart from the two busbars to define a clearance therebetween.

9. The rack busbar assembly of claim 5, wherein the lower section is provided with a through hole, and the rack busbar assembly further comprises an insulating sleeve disposed within the through hole, and
wherein the fastener passes through the insulating sleeve to electrically isolate the fastener from the thermal conductive element.

10. The rack busbar assembly of claim 3, wherein a maximum height of the thermal conductive element is between 40% and 80% of a maximum height of each of the two busbars.

11. The rack busbar assembly of claim 1, wherein the thermal conductive element is disposed below the lower portions of the two busbars.

12. The rack busbar assembly of claim 11, further comprising two separate thermal conductive insulating material layers respectively sandwiched between surfaces of the lower portions of the two busbars and the thermal conductive element.

13. The rack busbar assembly of claim 11, wherein the thermal conductive element comprises a liquid cooling plate defining the liquid flow channel therein,
wherein the liquid cooling plate comprises a positioning groove on a top surface thereof, and a bottom end of the insulating member is engaged in the positioning groove.

14. The rack busbar assembly of claim 13, wherein the liquid cooling plate further comprises a body portion having a slot and a cover plate enclosing the slot to form the liquid flow channel.

15. The rack busbar assembly of claim 13, wherein the thermal conductive element further comprises two extension walls extending upward from the liquid cooling plate to form a C-shaped structure.

16. The rack busbar assembly of claim 15, wherein a thickness of the lower portion of each busbar is less than a thickness of the upper portion to define a space accommodating the extension walls of the thermal conductive element.

17. The rack busbar assembly of claim 15, wherein the fastener passes through the lower portion of the busbar and the two extension walls of the thermal conductive element.

18. The rack busbar assembly of claim 11, wherein the fastening member comprises a vertical portion extending along the height direction, the vertical portion abutting against the lower portion of the busbar,
wherein a bending platform extends from the vertical portion to a bottom surface of the thermal conductive element to form an L-shaped structure.

19. The rack busbar assembly of claim 1, wherein the thermal conductive element comprises a plurality of connectors spaced apart along the longitudinal direction,
wherein the housing comprises a bottom wall provided with openings allowing the connectors to pass therethrough.

20. The rack busbar assembly of claim 1, wherein a plurality of fins are disposed in the liquid flow channel to divide the liquid flow channel into a plurality of sub-flow channels.
